(19) United States
(12) Patent Application Publication
(10) Pub. No.: US 2024/0281739 A1
(43) Pub. Date: Aug. 22, 2024

(54) WORK SIMULATION SYSTEM, WORK SIMULATION METHOD, AND NON-TRANSITORY STORAGE MEDIUM

(71) Applicant: TOYOTA JIDOSHA KABUSHIKI KAISHA, Toyota-shi (JP)

(72) Inventor: Noriaki SAKAI, Nisshin-shi (JP)

(73) Assignee: TOYOTA JIDOSHA KABUSHIKI KAISHA, Toyota-shi (JP)

(21) Appl. No.: 18/527,456

(22) Filed: Dec. 4, 2023

(30) Foreign Application Priority Data
Feb. 17, 2023 (JP) 2023-023067

(51) Int. Cl. G06Q 10/0633; G06Q 10/0631

(52) U.S. Cl. CPC G06Q 10/0633; G06Q 10/06316

(57) ABSTRACT

A work simulation system is configured to output a state in which a virtual character in a virtual space executes predetermined work on a work target object. The work simulation system includes an acquisition unit, a determination unit, and an output unit. The acquisition unit is configured to acquire information that indicates a position of a work portion of the work target object and information that indicates an approaching direction in which the virtual character approaches the work portion. The determination unit is configured to determine a posture that is suitable for work to be executed on the work portion by the virtual character facing the approaching direction. The output unit is configured to output the posture determined by the determination unit.

### CROSS-REFERENCE TO RELATED APPLICATION

This application claims priority to Japanese Patent Application No. 2023-023067 filed on Feb. 17, 2023, incorporated herein by reference in its entirety.

### BACKGROUND

### 1. Technical Field

The present disclosure relates to a work simulation system, a work simulation method, and a non-transitory storage medium.

### 2. Description of Related Art

Japanese Unexamined Patent Application Publication No. 2020-071581 (JP 2020-071581 A) discloses a construction simulation device that arranges and moves a character simulating a worker at a work site in a virtual world. The construction simulation device disclosed in JP 2020-071581 A simulates appropriate arrangement of a worker for work on a structure at a work site.

### SUMMARY

While a character simulating a worker moves to the vicinity of a structure in the work simulation device disclosed in JP 2020-071581 A discussed above, the work state of the character is not reflected. Therefore, the device involves a problem that the worker cannot recognize how to perform work even when the worker checks the simulation result.

The present disclosure provides a work simulation system, a work simulation method, and a non-transitory storage medium that can present a simulation result that enables a worker to easily recognize how to perform work.

A work simulation system according to the present disclosure is configured to output a state in which a virtual character in a virtual space executes predetermined work on a work target object. The work simulation system includes an acquisition unit, a determination unit, and an output unit. The acquisition unit is configured to acquire information that indicates a position of a work portion of the work target object and information that indicates an approaching direction in which the virtual character approaches the work portion. The determination unit is configured to determine a posture that is suitable for work to be executed on the work portion by the virtual character facing the approaching direction. The output unit is configured to output the posture determined by the determination unit.

The work simulation system according to the present disclosure determines and outputs a posture that is suitable for work to be executed by the virtual character facing the approaching direction in which the virtual character approaches the work portion. Therefore, it is possible to present a simulation result that enables a worker to easily recognize how to perform the work.

The approaching direction may be determined based on a content of the work. With such a configuration, a posture that is suitable for work to be executed on the work portion by the virtual character facing the approaching direction that matches the content of the work is determined and output. Therefore, it is possible to present a simulation result that enables a worker to easily recognize how to perform the work.

The approaching direction may be determined further based on information on an obstacle that hinders the work. With such a configuration, a posture that is suitable for work to be executed by the virtual character facing the approaching direction in which the virtual character approaches the work portion while avoiding an obstacle is determined and output. Therefore, it is possible to present a simulation result that enables a worker to easily recognize how to perform the work.

When a work position at which the virtual character works on the work portion is defined as a start point and a position of the work portion is defined as an end point, the approaching direction may be a direction from the start point to the end point.

The work simulation system may further include a display unit configured to receive an output from the output unit. The display unit may be configured to display: first display that displays the posture determined by the determination unit; second display that displays a list of work portions of the work target object; and third display that displays work information for the work portions.

The display unit may be configured to display the posture for a work portion selected from the list on the second display as the first display, and display work information for the selected work portion as the third display.

A work simulation method according to the present disclosure outputs a state in which a virtual character in a virtual space executes predetermined work on a work target object. The work simulation method causes a computer to execute processes including: acquiring information that indicates a position of a work portion of the work target object and information that indicates an approaching direction in which the virtual character approaches the work portion; determining a posture that is suitable for work to be executed on the work portion by the virtual character facing the approaching direction; and outputting the determined posture.

The work simulation method according to the present disclosure determines and outputs a posture that is suitable for work to be executed by the virtual character facing the approaching direction in which the virtual character approaches the work portion. Therefore, it is possible to present a simulation result that enables a worker to easily recognize how to perform the work.

The approaching direction may be determined based on a content of the work. The approaching direction may be determined further based on information on an obstacle that hinders the work. When a work position at which the virtual character works on the work portion is defined as a start point and a position of the work portion is defined as an end point, the approaching direction may be a direction from the start point to the end point.

In the work simulation method, the processes may further include: displaying the output posture on a display unit as first display; displaying a list of work portions of the work target object on the display unit as second display; and displaying work information for the work portions on the display unit as third display.

In the work simulation method, the processes may further include: displaying the posture for a work portion selected from the list on the second display as the first display; and displaying work information for the selected work portion as the third display.

A non-transitory storage medium according to the present disclosure stores an instruction for outputting a state in which a virtual character in a virtual space executes predetermined work on a work target object, the instruction being executable by one or more processors and causing the one or more processors to execute the following processes. The processes include: acquiring information that indicates a position of a work portion of the work target object and information that indicates an approaching direction in which the virtual character approaches the work portion;
determining a posture that is suitable for work to be executed on the work portion by the virtual character facing the approaching direction; and
outputting the determined posture.

The non-transitory storage medium according to the present disclosure makes it possible to determine and output a posture that is suitable for work to be executed by the virtual character facing the approaching direction in which the virtual character approaches the work portion. Therefore, it is possible to present a simulation result that enables a worker to easily recognize how to perform the work.

The approaching direction may be determined based on a content of the work. The approaching direction may be determined further based on information on an obstacle that hinders the work. When a work position at which the virtual character works on the work portion is defined as a start point and a position of the work portion is defined as an end point, the approaching direction may be a direction from the start point to the end point.

In the non-transitory storage medium, the processes may further include: displaying the output posture on a display unit as first display; displaying a list of work portions of the work target object on the display unit as second display; and displaying work information for the work portions on the display unit as third display.

In the non-transitory storage medium, the processes may further include: displaying the posture for a work portion selected from the list on the second display as the first display; and displaying work information for the selected work portion as the third display.

With the present disclosure, it is possible to provide a work simulation system, a work simulation method, and a non-transitory storage medium that can present a simulation result that enables a worker to easily recognize how to perform work.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is a block diagram illustrating a work simulation system according to a first embodiment;

FIG. 2 illustrates an example of a simulation result from the work simulation system according to the first embodiment;

FIG. 3 is a flowchart illustrating a work simulation method according to the first embodiment;

FIG. 4 is a plan view of an area around a tank on which a virtual character executes work;

FIG. 5 is a plan view of an area around the tank on which the virtual character executes work; and

FIG. 6 illustrates an example of a display unit as an output destination for work simulation systems according to the first embodiment and a second embodiment.

### DETAILED DESCRIPTION OF EMBODIMENTS

While the present disclosure will be described below by way of embodiments, the present disclosure is not limited to the following embodiments. All the components described in relation to the embodiments are not necessarily essential as means for solving the problem. In order to clarify the explanation, the following description and drawings have been omitted or simplified as appropriate. In each drawing, the same elements are given the same reference signs, and redundant explanations are omitted as necessary. As a matter of course, a right-handed xyz orthogonal coordinate system illustrated in the drawings is defined for convenience to describe the positional relationship among constituent elements. Normally, a positive z-axis direction is a vertically upward direction, and an xy plane is a horizontal plane.

### First Embodiment

### Work Simulation System

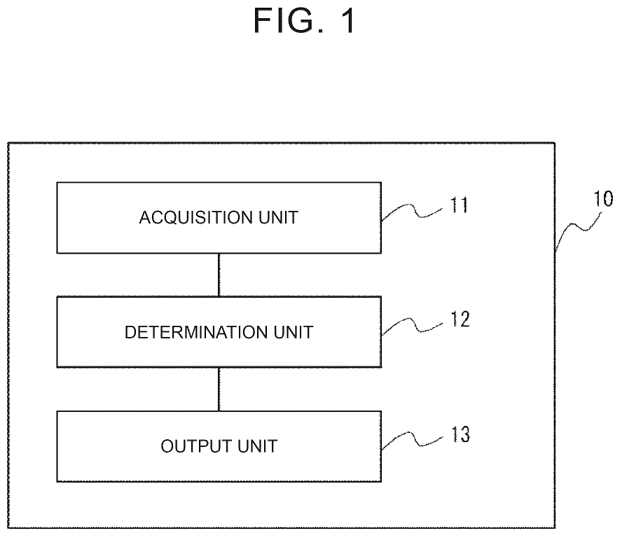

First, a work simulation system 10 according to a first embodiment will be described. FIG. 1 is a block diagram illustrating the work simulation system according to the first embodiment. The work simulation system 10 includes an acquisition unit 11, a determination unit 12, and an output unit 13. The work simulation system 10 outputs a state in which a virtual character in a virtual space executes predetermined work on a work target object. The work simulation system 10 can present, work performed in a production line, at a construction site, etc. in the virtual space to a worker in advance, for example.

Here, the virtual space is a virtual space constituted using a computer. The virtual space may be a space constituted by a computer network, that is, a space constituted using a plurality of computers, or a space constituted by a single computer that is used by a user. The virtual space is formed as a space in which structures and objects are arranged, for example. The virtual character is freely movable in the virtual space.

The acquisition unit 11 acquires information that indicates the position of a work portion of a work target object and information that indicates an approaching direction in which the virtual character approaches the work portion. The work target object is a finished product, a part, a structure, or a facility, for example. The work portion is a portion of the work target object on which the virtual character executes work and which has a predetermined area. The position of the work portion is the position of the center of the work portion. However, this is not limiting, and the position of the work portion may be a position indicated by any point of the work portion.

The positions of the work target object and the work portion may be represented using world coordinates, or may be represented using relative coordinates based on the work target object or the work portion.

When the virtual character executes work of attaching a cylinder head to an engine, for example, the work target object is the engine, and the work portion is a portion of the engine to which the cylinder head is to be attached.

The approaching direction in which the virtual character approaches the work portion is the direction (vector) from a start point to an end point when the work position of the virtual character is defined as the start point and the position of the work portion is defined as the end point.

The determination unit 12 determines a posture that is suitable for work to be executed on the work portion by the virtual character facing the approaching direction. Examples of the suitable posture include a half-sitting posture when the virtual character executes work of lifting up a manhole cover. Other examples of the suitable posture include a posture of grasping a ladder with both hands with one foot on the ladder when the virtual character executes work of climbing up the ladder.

The output unit 13 outputs the posture determined by the determination unit 12 as a simulation result. More specifically, the output unit 13 generates a signal that is necessary to display the posture determined by the determination unit 12 as a simulation result.

Information output from the output unit 13 is transferred to an operation terminal via a network, for example, to be displayed on a monitor (not illustrated) of the operation terminal or output as a sound from a speaker (not illustrated). Thus, the output unit 13 can also be considered as a transmission unit that transmits information to an external terminal. This allows the worker to know the posture as a simulation result from the work simulation system 10. A display example at an output destination will be discussed later.

The work simulation system 10 also includes a computation unit such as a central processing unit (CPU), and a storage unit such as a random access memory (RAM) and a read only memory (ROM) that store various control programs, data, etc., although not illustrated. That is, the work simulation system 10 has a function as a computer, and performs various processes based on the various control programs etc.

Therefore, the functional blocks of the work simulation system 10 illustrated in FIG. 1, namely the acquisition unit 11, the determination unit 12, and the output unit 13, can be constituted by the CPU, the storage unit, and other circuits in term of hardware. Alternatively, the functional blocks can be implemented by the programs etc. stored in the storage unit in terms of software. That is, the functional blocks can be implemented in various forms by hardware, software, or a combination of both.

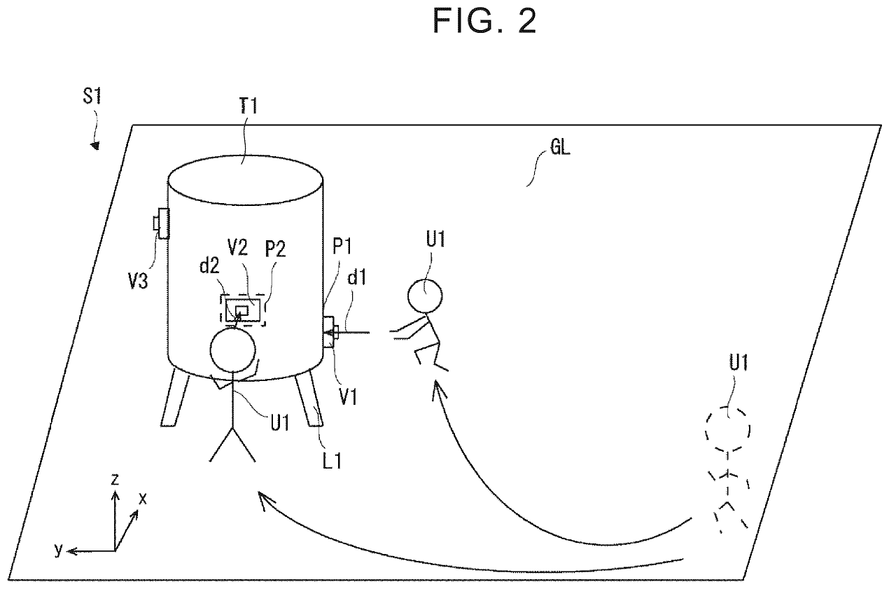

Subsequently, an example of the work simulation system will be described with reference to FIG. 2. FIG. 2 illustrates an example of a simulation result from the work simulation system according to the first embodiment. In FIG. 2, a virtual character U1 executes work of attaching a valve V1 to a tank T1 by welding, and work of attaching a valve V2 to the tank T1 by welding. As illustrated in FIG. 2, the installation height of the valves V1, V2, and V3 attached to the tank T1 from a ground surface GL is in the descending order of the valves V3, V2, and V1. The installation height of the valve V2 from the ground surface GL is about the same as the height of the virtual character U1.

First, a case where work simulation is performed for work in which the virtual character U1 attaches the valve V1 to the tank T1 by welding is described. In this case, the work target object is the tank T1, and a work portion P1 is a portion of the tank T1 to which the valve V1 is to be attached.

The acquisition unit 11 acquires information that indicates the position of the work portion P1. The acquisition unit 11 also acquires information that indicates the approaching direction in which the virtual character U1 approaches the work portion P1. As illustrated in FIG. 2, the approaching direction in which the virtual character U1 approaches the work portion P1 is a direction d1 (positive y-axis direction). The direction d1 is a direction in which the virtual character U1 can easily weld the valve V1 to the work portion P1.

Next, the determination unit 12 determines a posture that is suitable for work to be executed on the work portion P1 by the virtual character U1 facing the approaching direction d1. In the example illustrated in FIG. 2, the virtual character U1 executes work of welding the valve V1 to the work portion P1, the valve V1 being at a low installation height from the ground surface GL. Therefore, the determination unit 12 determines a state in which the virtual character U1 is crouching as a suitable posture.

In this case, the output unit 13 generates a signal etc. that is necessary for a display unit (not illustrated) to display the posture determined by the determination unit 12, that is, a situation in which the virtual character U1 executes work on the work portion P1 in a crouching state, as a simulation result, and outputs such a signal etc. to the display unit.

In this manner, the work simulation system 10 determines a crouching state as a posture that is suitable for the virtual character U1 to execute work of welding the valve V1 to the work portion P1, and outputs the determination result. Consequently, it is possible to present a simulation result that enables a worker that executes work of welding the valve V1 to the work portion P1 to easily recognize how to perform the work.

Subsequently, a case where work simulation is performed for work in which the virtual character U1 attaches the valve V2 to the tank T1 by welding is described. In this case, the work target object is the tank T1, and a work portion P2 is a portion of the tank T1 to which the valve V2 is to be attached.

The acquisition unit 11 acquires information that indicates the position of the work portion P2. The acquisition unit 11 also acquires information that indicates the approaching direction in which the virtual character U1 approaches the work portion P2. As illustrated in FIG. 2, the approaching direction in which the virtual character U1 approaches the work portion P2 is a direction d2 (positive x-axis direction). The direction d2 is a direction in which the virtual character U1 can easily weld the valve V2 to the work portion P2.

Next, the determination unit 12 determines a posture that is suitable for work to be executed on the work portion by the virtual character U1 facing the approaching direction d2. In the example illustrated in FIG. 2, the virtual character U1 executes work of welding the valve V2 to the work portion P2, the valve V2 being at an installation height that is about the same as the height of the virtual character U1 from the ground surface GL. Therefore, the determination unit 12 determines a state in which the virtual character U1 is standing as a suitable posture.

In this case, the output unit 13 generates a signal that is necessary for a display unit (not illustrated) to display the posture determined by the determination unit 12, that is, a situation in which the virtual character U1 executes work on the work portion P2 in a standing state, as a simulation result, and outputs such a signal to the display unit (not illustrated).

In this manner, the work simulation system 10 determines a standing state as a posture that is suitable for the virtual character U1 to execute work of welding the valve V2 to the work portion P2, and outputs the determination result. Consequently, it is possible to present a simulation result that enables a worker that executes work of welding the valve V2 to the work portion P2 to easily recognize how to perform the work.

In the example illustrated in FIG. 2, there is one approaching direction in which the virtual character U1 approaches the work portion P2. However, this is not limiting, and there may be two or more approaching directions in which the virtual character U1 approaches the work portion P2. In this case, a suitable posture is determined for each of the approaching directions in which the virtual character U1 approaches the work portion P2.

While the work portion P2 is a static portion in the example illustrated in FIG. 2, the work portion P2 may be a dynamic portion. In this case, the acquisition unit 11 acquires information that indicates the position of the work portion P2 and the approaching direction in which the virtual character U1 approaches the work portion P2 that are continuously varied in accordance with movement of the work portion P2. The determination unit 12 determines a posture that is suitable for work to be executed on the work portion by the virtual character U1 facing each approaching direction.

A route search algorithm may be employed as a method of moving the virtual character U1 to a position at which work of welding the valve V1 or the valve V2 is to be executed. This eliminates the need for a specific instruction for a route of movement of the virtual character U1. The coordinates and the height for movement may be corrected based on the height of the ground surface directly under or around the position at which work is to be executed.

The determination unit 12 may further determine information about the posture of the virtual character U1 in more detail. In the example illustrated in FIG. 2, the determination unit 12 may determine a state including the degree of tilt of a neck or a body, such as the virtual character U1 executing work in a posture with his/her face slightly looking into the work portion P2 while supporting the valve from the lower side using his/her left hand and applying a welding rod to the valve using his/her right hand.

The determination unit 12 may determine a distance between a location at which the virtual character U1 maintains a posture that is suitable for executing work and the valve V1 or the valve V2. When specifying a position, it is necessary to designate coordinates. In this event, it is only necessary to adjust one parameter for the distance since the approaching direction has been determined, which makes it easy to specify a position. When determining a distance, in addition, the determination unit 12 may use a default value that indicates a distance that facilitates human work, since the distance that facilitates human work is roughly determined.

While the virtual character U1 in the crouching state or the standing state is illustrated in the example illustrated in FIG. 2, a point, an arrow, or a text message that indicates movement of the virtual character U1 may be indicated without using the virtual character U1. For example, when the virtual character U1 illustrated in FIG. 2 is in the crouching state, a text message saying “Crouch” may be indicated together with a downward arrow.

In the work simulation system according to the first embodiment, in addition, it is not necessary to take the trouble of re-entering a setting condition about an arca around the work position. In the example illustrated in FIG. 2, a leg LI of the tank T1 is positioned on the side of the left leg of the virtual character U1 welding the valve V1, but is positioned on the side of the right left of the virtual character U2 welding the valve V2. Even in such a case, it is not necessary to take the trouble of re-entering a setting condition about an area around the work position in each work simulation.

That is, while the virtual character U1 simulating a human has high degrees of freedom and normally requires fine work instructions and takes time, the work simulation system according to the first embodiment eliminates the need for time for work instructions.

### Work Simulation Method

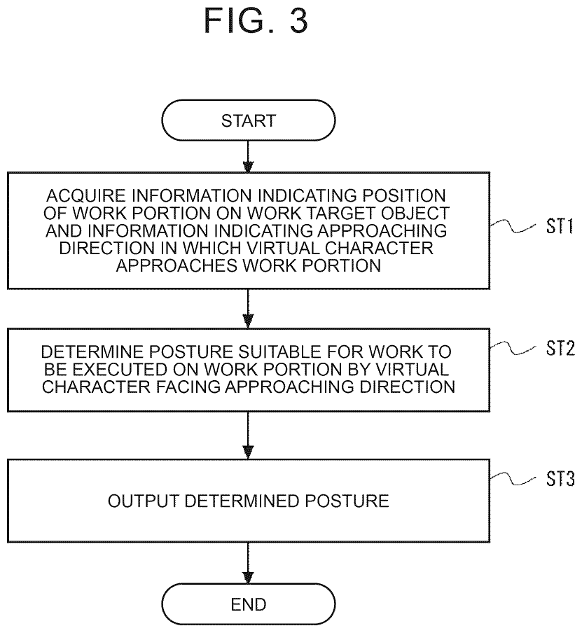

Subsequently, a work simulation method according to the first embodiment will be described. FIG. 3 is a flowchart illustrating a work simulation method according to the first embodiment.

First, information that indicates the position of a work portion on a work target object and information that indicates the approaching direction in which a virtual character approaches the work portion are acquired (step ST1). Next, a posture that is suitable for work to be executed on the work portion by the virtual character facing an approaching direction is determined (step ST2). Next, the determined posture is output as a simulation result.

In this manner, the work simulation system according to the first embodiment determines a posture that is suitable for work to be executed on the work portion by the virtual character facing an approaching direction, and outputs the determined posture. Consequently, it is possible to present a simulation result that enables a worker to easily recognize how to perform work.

### Second Embodiment

### Work Simulation System

Next, a work simulation system according to a second embodiment will be described. The work simulation system according to the second embodiment includes an acquisition unit, a determination unit, and an output unit, as with the work simulation system 10 according to the first embodiment. The work simulation system according to the second embodiment is different from the work simulation system according to the first embodiment in the approaching direction acquired by the acquisition unit. The other configuration of the work simulation system according to the second embodiment is the same as that of the work simulation system 10 according to the first embodiment, and therefore will not be described.

In the work simulation system according to the second embodiment, the approaching direction in which a virtual character approaches a work portion is determined based on the content of the work. The content of the work includes the type of the work, the viewability of a work target portion, the case in handling a tool to be used for the work, and the case in applying a force to the tool to be used for the work.

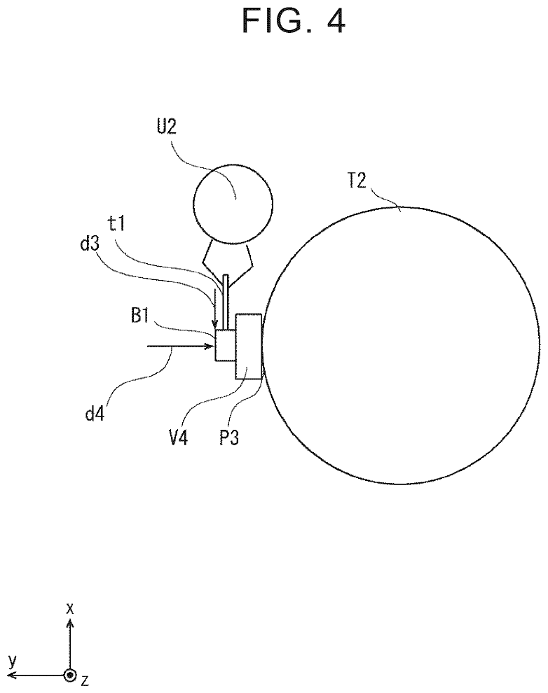

An example of the work simulation system according to the second embodiment will be described with reference to FIG. 4. FIG. 4 is a plan view of an area around a tank on which a virtual character executes work. In FIG. 4, a virtual character U2 executes work of attaching a valve V4 to a tank T2 and work of getting closer to check the degree to which the valve V4 attached to the tank T2 is tightened. The virtual character U2 attaches the valve V4 to the tank T2 by tightening a bolt B1 by handling a tool t1 using both hands. In the example illustrated in FIG. 4, for either work, the work target object is the tank T2, and a work portion P3 is a portion of the tank T2 to which the valve V4 is to be attached.

First, a case where work simulation is performed for work in which the virtual character U2 attaches the valve V4 to the tank T2 is described. In this case, the content of the work includes attaching the valve V4 to the tank T2 by tightening the bolt B1 by handling the tool t1 using both hands. In the example illustrated in FIG. 4, the tool t1 is brought into contact with a side surface of the bolt B1 when tightening the bolt B1 by handling the tool t1.

The acquisition unit acquires information that indicates the position of the work portion P3. The acquisition unit also acquires information that indicates the approaching direction in which the virtual character U2 approaches the work portion P3. In this case, the approaching direction in which the virtual character U2 approaches the work portion P3 is determined based on the content of the work.

As illustrated in FIG. 4, the approaching direction in which the virtual character U2 approaches the work portion P3 is a direction d3 (negative x-axis direction). The direction d3 is a direction in which the virtual character U2 can easily apply a force to the tool t1 using both hands when tightening the bolt B1.

Next, the determination unit determines a posture that is suitable for work to be executed on the work portion by the virtual character U2 facing the approaching direction d3. In the example illustrated in FIG. 4, the determination unit determines, as a suitable posture, a standing state in which the virtual character U2 grasps the tool t1 using both hands with the longitudinal direction of the tool t1 coinciding with the direction d3.

In this case, the output unit generates a signal that is necessary for a display unit (not illustrated) to display the posture determined by the determination unit, that is, a situation in which the virtual character U2 executes work on the work portion P3 in a standing state while grasping the tool t1 using both hands with the longitudinal direction of the tool t1 coinciding with the direction d3, as a simulation result, and outputs such a signal to the display unit (not illustrated).

In this manner, by acquiring the approaching direction, the work simulation system changes direction such that the virtual character U2 faces the approaching direction after moving to the work portion. Further, it is possible to simulate a state in which the work portion is approached from an appropriate position, since there is not only information on an area around the work portion.

Subsequently, a case where work simulation is performed for work in which the virtual character U2 gets closer to check the degree to which the valve V4 attached to the tank T2 is tightened is described. In this case, the content of the work includes checking the degree to which the valve V4 is tightened to the tank T2.

In this case, as illustrated in FIG. 4, the approaching direction in which the virtual character U2 approaches the work portion P3 is a direction d4 (negative y-axis direction). The direction d4 is a direction in which the virtual character U2 can easily check the degree to which the valve V4 is tightened to the tank T2. The determination unit determines a state in which the virtual character U2 is standing as a suitable posture. The determination unit may further determine a posture in which the virtual character U2 slightly looks into the work portion P3 as a suitable posture.

The approaching direction is not limited to one direction when the virtual character U2 gets closer to check whether no tool is left behind around the tank T2. Therefore, the acquisition unit may acquire information that indicates a plurality of approaching directions in which the virtual character U2 approaches the work portion P3. In this case, the determination unit determines a posture that is suitable for work to be executed on the work portion by the virtual character U2 facing each of the approaching directions. In this manner, there may be a plurality of approaching directions in which the work portion is approached, and one of the plurality of directions may be selected. Alternatively, the approaching direction in which the work portion is approached may be determined such that one of a plurality of directions is a desirable direction from a standing position during work and a different direction is a direction in which the work portion is approached by a tool, for example.

In this case, the output unit generates a plurality of signals that is necessary for a display unit (not illustrated) to display a plurality of postures determined by the determination unit, as a simulation result, and outputs such signals to the display unit (not illustrated).

In this manner, the work simulation system according to the second embodiment determines an approaching direction in which the virtual character approaches the work portion based on the content of the work. Consequently, a posture that is suitable for work to be executed on the work portion by the virtual character facing an approaching direction that matches the content of the work is determined and output. Therefore, it is possible to present a simulation result that enables a worker to easily recognize how to perform the work.

Here, in the work simulation system according to the second embodiment, the approaching direction in which the virtual character approaches the work portion may be determined further based on information on obstacles that hinder work. Examples of the obstacles that hinder work include virtual characters of a wall, a groove, etc. that hinder the virtual character from executing work while facing the direction of the work portion around the work portion.

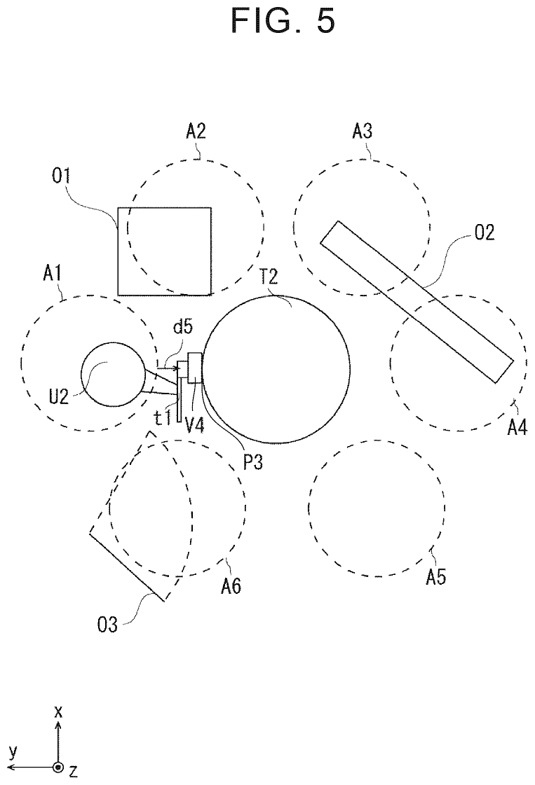

An approaching direction of the virtual character U2 determined based on information on obstacles will be described with reference to FIG. 5. FIG. 5 is a plan view of an area around the tank on which the virtual character executes work. In FIG. 5, as in FIG. 4, the virtual character U2 executes work of attaching the valve V4 to the tank T2. The virtual character U2 attaches the valve V4 to the tank T2 by tightening the bolt B1 by handling the tool t1 using both hands. In the example illustrated in FIG. 5, when tightening the bolt B1 by handing the tool t1, the tool t1 is brought into contact with a side surface of the bolt B1. In the example illustrated in FIG. 5, the work target object is the tank T2, and the work portion P3 is a portion of the tank T2 to which the valve V4 is to be attached.

As illustrated in FIG. 5, a hole O1, a wall O2, and a door O3 are disposed around the tank T2. The hole O1, the wall O2, and the door O3 are obstacles that hinder the work of the virtual character U2 fixing the valve V4 to the tank T2 by tightening the bolt B1.

Here, an example in which an approaching direction in which the virtual character U2 approaches the work portion P3 is determined by scoring candidate points A1 to A6 around the tank T2 will be described with reference to Table 1 and FIG. 5.

In the example illustrated in FIG. 5, the hole O1 is positioned on the candidate point A2. The wall O2 is positioned on the candidate point A3 and the candidate point A4. The door O3 is positioned on the candidate point A6 when in an open state, and not positioned on the candidate point A6 when in a closed state.

Table 1 indicates the result of scoring the candidate points A1 to A6 illustrated in FIG. 5. Scores of the candidate points A1 to A6 in Table 1 indicate that a candidate point with a higher score is more suitable for work of the virtual character U2 attaching the valve V4 to the tank T2.

TABLE 1

Candidate point

| | A1 | A2 | A3 | A4 | A5 | A6 |
|---|---|---|---|---|---|---|
| Score | 10 | 0 | 0 | 0 | 0 | 8 |

First, the scores of the candidate points A2, A3, and A4 at which the hole O1 and the wall O2 as obstacles are positioned are described. As illustrated in FIG. 5, the hole O1 is positioned on the candidate point A2, and the virtual character U2 cannot execute work while facing the direction of the valve V4 at the position of the candidate point A2. Therefore, the candidate point A2 has a score of 0 as indicated in Table 1.

As illustrated in FIG. 5, the wall O2 is positioned on the candidate points A3 and A4, and the virtual character U2 cannot execute work while facing the direction of the valve V4 at the positions of the candidate points A3 and A4. Therefore, the candidate points A3 and A4 have a score of 0 as indicated in Table 1.

Next, the score of the candidate point A6 at which the door O3 as an obstacle is positioned is described. As illustrated in FIG. 5, the door O3 is positioned on the candidate point A6 when in an open state, and not positioned on the candidate point A6 when in a closed state. That is, the virtual character U2 can execute work while facing the direction of the valve V4 at the candidate point A6 in some cases, and cannot in the other cases. Therefore, the candidate point A6 has a score of 8 as indicated in Table 1.

Next, the scores of the candidate points A1 and A5 at which the hole O1, the wall O2, and the door O3 as obstacles are not positioned are described. As illustrated in FIG. 5, no obstacle is positioned on the candidate point A1, and the virtual character U2 can execute work while facing the direction of the valve V4 at the position of the candidate point A1. Therefore, the candidate point A1 has a score of 10 as indicated in Table 1.

As illustrated in FIG. 5, no obstacle is positioned on the candidate point A5. However, the tool t1 cannot be used at the position of the candidate point A5, which is distanced from the work portion P3. Hence, the virtual character U2 cannot execute work while facing the direction of the valve V4 at the position of the candidate point A5. Therefore, the candidate point A5 has a score of 0 as indicated in Table 1.

From the above, the score of the candidate point A1 is the highest of those of the candidate points A1 to A6 as indicated in Table 1. That is, the candidate point A1 is a candidate point that is suitable for work of the virtual character U2 attaching the valve V4 to the tank T2.

In this case, the approaching direction in which the virtual character U2 approaches the work portion P3 is a direction d5 (negative y-axis direction) from a start point to an end point when the position of the candidate point A1 is defined as the start point and the work portion P3 is defined as the end point. In the example illustrated in FIG. 5, the determination unit determines, as a suitable posture, a standing state in which the virtual character U2 grasps the tool t1 using both hands with the longitudinal direction of the tool t1 coinciding with a direction (x-axis direction) that is orthogonal to the direction d5 by 90 degrees.

Further, the output unit generates a signal that is necessary for a display unit (not illustrated) to display the posture determined by the determination unit, that is, a situation in which the virtual character U2 executes work on the work portion P3 in a standing state while grasping the tool t1 using both hands with the longitudinal direction of the tool t1 coinciding with a direction (x-axis direction) that is orthogonal to the direction d5 by 90 degrees, as a simulation result, and outputs such a signal to the display unit (not illustrated).

In this manner, in the work simulation system according to the second embodiment, the virtual character U2 executes work while facing the direction d3 when no obstacles are positioned around the tank T2 as illustrated in FIG. 4. On the other hand, the virtual character U2 executes work while facing the direction d5 when obstacles are positioned around the tank T2 as illustrated in FIG. 5.

In other words, the virtual character U2 cannot execute work while facing the direction d3 in which the virtual character U2 can easily apply a force to the tool t1 using both hands, since obstacles are positioned around the tank T2. Therefore, the virtual character U2 executes work while facing the direction d5 from a start point to an end point when the candidate point A1 that is the most suitable for work is defined as the start point and the work portion P3 is defined as the end point.

The scores indicated in Table 1 are determined in accordance with whether an obstacle is located at the candidate point, whether the virtual character U2 can execute work while facing the direction of the work portion from the position of the candidate point, and whether a tool can be applied to the work portion from the position of the candidate point. However, this is not limiting, and scores may be determined with focus placed on one of the plurality of items. For example, scores may be determined with focus placed on whether an obstacle is located at the candidate point. In another example, scores may be determined with focus placed on the cost (work cost) of work to be performed on the work portion from the candidate point.

In the example illustrated in FIG. 5, the candidate points A1 to A6 are disposed such that a shape obtained by connecting the center points of the candidate points A1 to A6 forms a hexagon around the tank T2. However, this is not limiting, and candidate points may be disposed in any manner around the tank T2.

In this manner, the work simulation system according to the second embodiment may determine an approaching direction in which the virtual character approaches the work portion further based on information on obstacles that hinder work. Consequently, a posture that is suitable for work to be executed on the work portion by the virtual character facing a direction that matches the content of the work while avoiding obstacles is determined. Therefore, it is possible to present a simulation result that enables a worker to easily recognize how to perform the work.

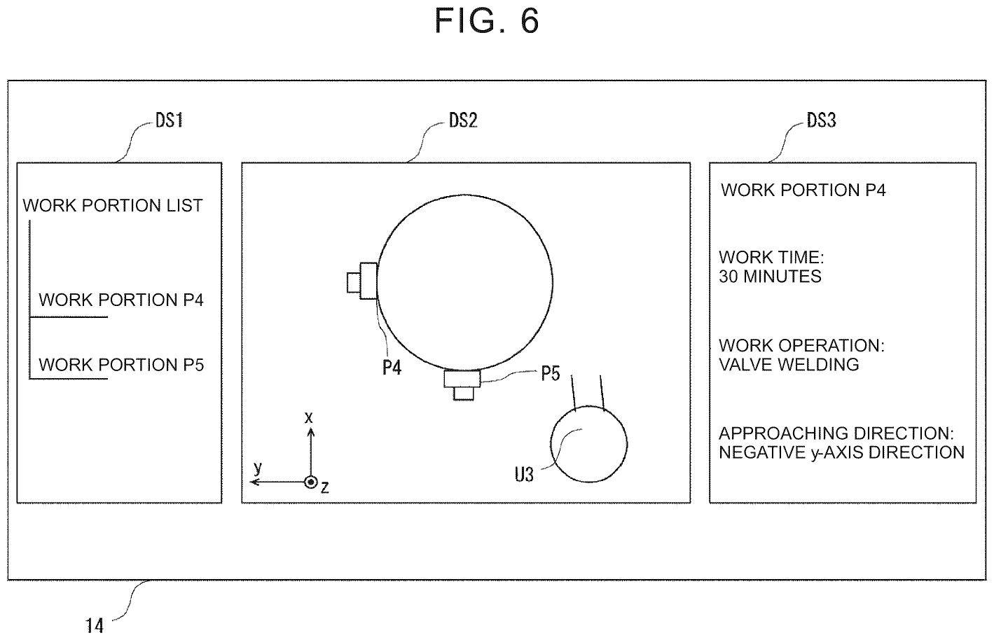

Here, the display unit as an output destination for the work simulation systems according to the first and second embodiments discussed above will be described with reference to FIG. 6. FIG. 6 illustrates an example of the display unit as an output destination for the work simulation systems according to the first and second embodiments. As illustrated in FIG. 6, a display unit 14 displays work portion list display DS1, simulation state display DS2, and work portion information display DS3. By selecting one of the work portions P4 and P5 in the work portion list display DS1 displayed on the display unit 14, the worker can switch to display the simulation state display DS2 and the work portion information display DS3 at the selected work portion. The worker can also select one of the work portions P4 and P5 displayed in the simulation state display DS2.

As illustrated in FIG. 6, a simulation result from the work simulation systems according to the first and second embodiments discussed above is displayed in the simulation state display DS2. While the work portions P4 and P5 are fixed portions in the simulation state display DS2 illustrated in FIG. 6, the work portions P4 and P5 may be movable portions. That is, when the work portions have movement loci, the worker may provide a work instruction by tracing, in the simulation state display DS2, a state in which a virtual character U3 executes work while moving.

In this manner, a simulation result for a selected work portion can be displayed by selecting one of the work portions P4 and P5 on the display unit 14. Since the worker can grasp the coordinates of the work portion and the approaching direction visually, rather than through numerical values, it is easier to understand the work place and the standing position for the work portion. In addition, it is possible to centrally manage information by concentrating information that is necessary for work portions at the display unit 14, which improves the efficiency in check work and change work.

While a virtual character that simulates a worker is illustrated as an example of the virtual character that executes work in the work simulation systems according to the first and second embodiments discussed above, the virtual character may simulate a construction machine or a robot that can execute work on a work portion while moving. In this manner, the virtual character is not limited to a virtual character that simulates a human, and may be a virtual character that simulates a non-human work subject.

A part or all of the processes in the work simulation systems according to the first and second embodiments discussed above can be implemented as a computer program. Such a program can be stored using various types of non-transitory computer-readable media, and supplied to a computer. The non-transitory computer-readable media include various types of tangible storage media. Examples of the non-transitory computer-readable media include magnetic storage media (e.g. flexible disks, magnetic tapes, and hard disk drives), magneto-optical storage media (e.g. magneto-optical disks), compact disc (CD) read only memory (ROM), compact disc recordable (CD-R), compact disc rewritable (CD-R/W), and semiconductor memory (e.g. mask ROM, programmable ROM (PROM), erasable PROM (EPROM), flash ROM, and random access memory (RAM)). Alternatively, the program may be supplied to the computer by various types of transitory computer-readable media. Examples of the transitory computer-readable media include electrical signals, optical signals, and electromagnetic waves. The transitory computer-readable media can supply the program to the computer via a wired communication path such as an electric wire and an optical fiber or a wireless communication path.

The present disclosure is not limited to the above embodiments, and can be modified as appropriate without departing from the spirit and scope of the present disclosure.

What is claimed is:

1. A work simulation system configured to output a state in which a virtual character in a virtual space executes predetermined work on a work target object, comprising:
an acquisition unit configured to acquire information that indicates a position of a work portion of the work target object and information that indicates an approaching direction in which the virtual character approaches the work portion;
a determination unit configured to determine a posture that is suitable for work to be executed on the work portion by the virtual character facing the approaching direction; and
an output unit configured to output the posture determined by the determination unit.

2. The work simulation system according to claim 1, wherein the approaching direction is determined based on a content of the work.

3. The work simulation system according to claim 2, wherein the approaching direction is determined further based on information on an obstacle that hinders the work.

4. The work simulation system according to claim 1, wherein when a work position at which the virtual character works on the work portion is defined as a start point and a position of the work portion is defined as an end point, the approaching direction is a direction from the start point to the end point.

5. The work simulation system according to claim 1, further comprising a display unit configured to receive an output from the output unit, wherein the display unit is configured to display:
first display that displays the posture determined by the determination unit;
second display that displays a list of work portions of the work target object; and
third display that displays work information for the work portions.

6. The work simulation system according to claim 5, wherein the display unit is configured to display the posture for a work portion selected from the list on the second display as the first display, and display work information for the selected work portion as the third display.

7. A work simulation method of outputting a state in which a virtual character in a virtual space executes predetermined work on a work target object, the work simulation method causing a computer to execute processes comprising:
acquiring information that indicates a position of a work portion of the work target object and information that indicates an approaching direction in which the virtual character approaches the work portion;
determining a posture that is suitable for work to be executed on the work portion by the virtual character facing the approaching direction; and
outputting the determined posture.

8. The work simulation method according to claim 7, wherein the approaching direction is determined based on a content of the work.

9. The work simulation method according to claim 8, wherein the approaching direction is determined further based on information on an obstacle that hinders the work.

10. The work simulation method according to claim 7, wherein when a work position at which the virtual character works on the work portion is defined as a start point and a position of the work portion is defined as an end point, the approaching direction is a direction from the start point to the end point.

11. The work simulation method according to claim 7, the processes further comprising:
displaying the output posture on a display unit as first display;
displaying a list of work portions of the work target object on the display unit as second display; and
displaying work information for the work portions on the display unit as third display.

12. The work simulation method according to claim 11, the processes further comprising:
displaying the posture for a work portion selected from the list on the second display as the first display; and
displaying work information for the selected work portion as the third display.

13. A non-transitory storage medium storing an instruction for outputting a state in which a virtual character in a virtual space executes predetermined work on a work target object, the instruction being executable by one or more processors and causing the one or more processors to execute processes comprising:
acquiring information that indicates a position of a work portion of the work target object and information that indicates an approaching direction in which the virtual character approaches the work portion;
determining a posture that is suitable for work to be executed on the work portion by the virtual character facing the approaching direction; and
outputting the determined posture.

14. The non-transitory storage medium according to claim 13, wherein the approaching direction is determined based on a content of the work.

15. The non-transitory storage medium according to claim 14, wherein the approaching direction is determined further based on information on an obstacle that hinders the work.

16. The non-transitory storage medium according to claim 13, wherein when a work position at which the virtual character works on the work portion is defined as a start point and a position of the work portion is defined as an end point, the approaching direction is a direction from the start point to the end point.

17. The non-transitory storage medium according to claim 13, the processes further comprising:
displaying the output posture on a display unit as first display;
displaying a list of work portions of the work target object on the display unit as second display; and
displaying work information for the work portions on the display unit as third display.

18. The non-transitory storage medium according to claim 17, the processes further comprising:
displaying the posture for a work portion selected from the list on the second display as the first display; and
displaying work information for the selected work portion as the third display.
